(19) United States
(12) Patent Application Publication
(10) Pub. No.: US 2026/0371686 A1
(43) Pub. Date: Nov. 19, 2026

(54) LDMOS TRANSISTOR WITH POLYSILICON MEMBERS AND FIELD PLATE CONTACT BETWEEN POLYSILICON MEMBERS AND RELATED METHOD

(71) Applicant: GlobalFoundries Singapore Pte. Ltd., Singapore (SG)

(72) Inventor: Bong Woong Mun, Singapore (SG)

(21) Appl. No.: 19/209,938

(22) Filed: May 16, 2025

(51) Int. Cl. H10D 64/00; H10D 30/01; H10D 30/65

(52) U.S. Cl. CPC H10D 64/112; H10D 30/0281; H10D 30/65

(57) ABSTRACT

An LDMOS transistor includes a semiconductor substrate, a polysilicon gate over a channel region in the semiconductor substrate, a source region to a first side of the polysilicon gate, and a drain region to a second, opposite side of the polysilicon gate. A metal, field plate layer is over the polysilicon gate, and a drift region is in the semiconductor substrate between the polysilicon gate and the drain region. A first polysilicon member is over the drift region, and a second polysilicon member is over the drift region. The first and second polysilicon members have a space therebetween, and a contact extends from the metal field plate layer and includes a lower portion positioned in the space between the first and second polysilicon members.

### BACKGROUND

The present disclosure relates to transistors, and more specifically, to a laterally diffused metal oxide semiconductor (LDMOS) transistor with a field plate contact between polysilicon members, and a related method.

Laterally diffused metal-oxide semiconductor (LDMOS) transistors are used in, for example, radio frequency (RF) devices. LDMOS transistors include, within a semiconductor substrate such as a fin, a p-well with a source region therein and an n-well with a drain region therein. A polysilicon gate extends over the p-well and n-well with the channel region in the p-well and a drift region in the n-well. Field plates are used to shape an electrical field around the polysilicon gate. One challenge with these devices is continuing to improve breakdown voltage and/or field plate performance.

### SUMMARY

All aspects, examples and features mentioned below can be combined in any technically possible way.

An aspect of the disclosure provides a laterally-diffused metal-oxide semiconductor (LDMOS) transistor, comprising: a semiconductor substrate; a polysilicon gate over a channel region in the semiconductor substrate; a source region to a first side of the polysilicon gate; a drain region to a second, opposite side of the polysilicon gate; a metal layer over the polysilicon gate; a drift region in the semiconductor substrate between the polysilicon gate and the drain region; a first polysilicon member over the drift region; a second polysilicon member over the drift region, the first and second polysilicon members having a first space therebetween; and a first contact extending from the metal layer and including a lower portion positioned in the first space between the first and second polysilicon members.

An aspect of the disclosure provides a laterally diffused metal-oxide semiconductor (LDMOS) transistor, comprising: a semiconductor substrate; a polysilicon gate over a channel region in the semiconductor substrate; a source region to a first side of the polysilicon gate; a drain region to a second, opposite side of the polysilicon gate; a metal field plate over the polysilicon gate; a drift region in the semiconductor substrate between the polysilicon gate and the drain region; a first polysilicon member over the drift region; a second polysilicon member over the drift region, the first and second polysilicon members having a first space therebetween; a first spacer in the first space adjacent the first polysilicon member; a second spacer in the first space adjacent the second polysilicon member; and a first contact extending from the metal field plate and including a lower portion positioned in the first space between the first and second polysilicon members, wherein a bottom of the lower portion of the first contact is vertically spaced and electrically isolated from the drift region by the first and second spacers.

An aspect of the disclosure provides a method, comprising: forming a polysilicon gate over a channel region in a semiconductor substrate; forming a first polysilicon member over the semiconductor substrate and a second polysilicon member over the semiconductor substrate, the first and second polysilicon members having a first space therebetween; forming a source region and a drain region on opposing sides of the polysilicon gate, wherein a drift region is between the polysilicon gate and the drain region in the semiconductor substrate and the first polysilicon member the second polysilicon member are over the drift region; forming a first contact including a lower portion positioned in the first space between the first and second polysilicon members; and forming a metal layer over the polysilicon gate and the first and second polysilicon members, the metal layer contacting the first contact.

Two or more aspects described in this disclosure, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The embodiments of this disclosure will be described in detail, with reference to the following figures, wherein like designations denote like elements, and wherein:

FIG. 1 shows a cross-sectional view of a preliminary structure for a method to form a laterally diffused metal-oxide (LDMOS) transistor according to embodiments of the disclosure;

FIG. 2 shows a cross-sectional view of forming (part of) a polysilicon gate over a channel region and first and second polysilicon members over a drift region in a semiconductor substrate according to embodiments of the disclosure;

FIG. 3 shows a cross-sectional view forming spacers for a polysilicon gate and first and second polysilicon members according to embodiments of the disclosure;

FIG. 4 shows a cross-sectional view of forming a source region and a drain region for the LDMOS transistor according to embodiments of the disclosure;

FIGS. 5A-B show corresponding cross-sectional and top-down views, respectively, of an LDMOS transistor according to embodiments of the disclosure;

FIGS. 6A-B show corresponding cross-sectional and top-down views, respectively, of an LDMOS transistor according to other embodiments of the disclosure;

FIGS. 7A-B show corresponding cross-sectional and top-down views, respectively, of an LDMOS transistor according to additional embodiments of the disclosure;

FIGS. 8A-B show corresponding cross-sectional and top-down views, respectively, of an LDMOS transistor according to yet other embodiments of the disclosure; and

FIGS. 9A-B show corresponding cross-sectional and top-down views, respectively, of an LDMOS transistor according to further embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (A) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

Embodiments of the disclosure include laterally diffused metal-oxide semiconductor (LDMOS) transistors, and a related method. An LDMOS transistor includes a semiconductor substrate, a polysilicon gate over a channel region in the semiconductor substrate, a source region to a first side of the polysilicon gate, and a drain region to a second, opposite side of the polysilicon gate. A metal (field plate) layer is over the polysilicon gate, and a drift region is in the semiconductor substrate between the polysilicon gate and the drain region. A first polysilicon member is over the drift region, and a second polysilicon member is over the drift region. The first and second polysilicon members (also part of field plate) have a space therebetween, and a contact extends from the metal layer and includes a lower portion positioned in the space between the first and second polysilicon members. The polysilicon members in the drift region improve the prompt degradation of the LDMOS transistor due to, for example, the high-quality gate dielectric layer at the bottom of the polysilicon members. The contact of the LDMOS transistor also results in increased breakdown voltage.

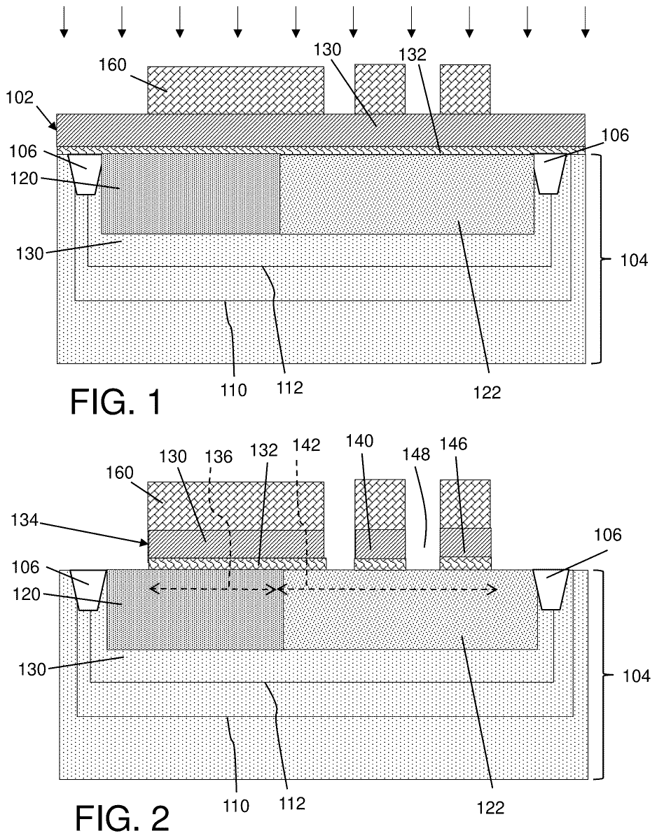

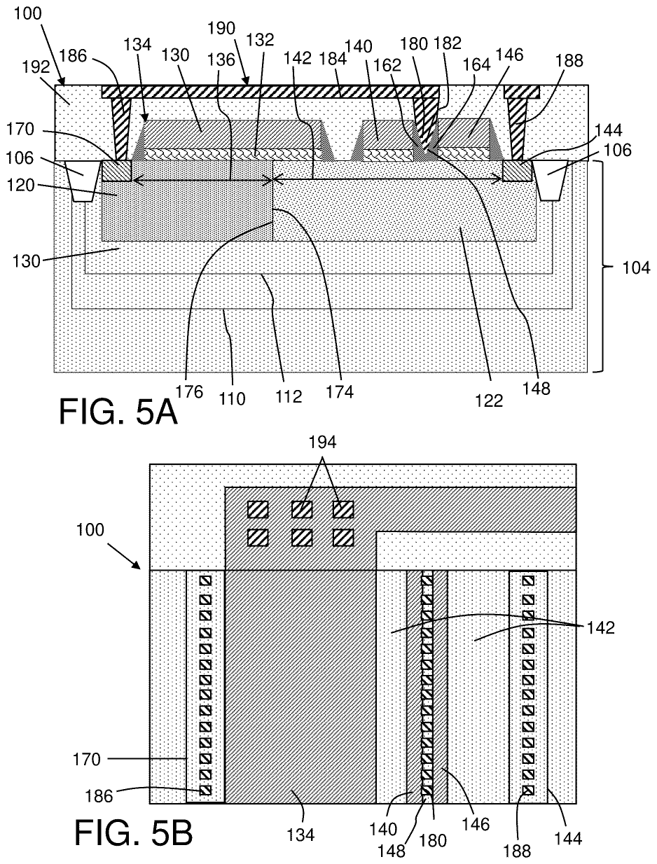

FIGS. 1-5A show cross-sectional views of a method to form LDMOS transistors 100 (FIGS. 5A-9B) according to various embodiments of the disclosure. For purposes of description, LDMOS transistors 100 (FIGS. 5A-9B) may be implemented as a FinFET, but it is emphasized that it can also be applied in other types of MOS devices, e.g., bulk, planar semiconductor substrates.

FIG. 1 shows a cross-sectional view of a preliminary structure 102 configured for forming LDMOS transistor 100 (FIGS. 5A-9B). Preliminary structure 102 includes a semiconductor substrate 104. Semiconductor substrate 104 may be formed using any now known or later developed technology, e.g., with a semiconductor fin or bulk semiconductor. Semiconductor substrate 104 may include but is not limited to silicon, germanium, silicon germanium, silicon carbide, and those consisting essentially of one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable substrates include II-VI compound semiconductors having a composition Zn_{A1}Cd_{A2}Se_{B1}Te_{B2}, where A1, A2, B1, and B2 are relative proportions each greater than or equal to zero and A1+A2+B1+B2=1 (1 being a total mole quantity). Furthermore, a portion or entire semiconductor substrate may be strained. In certain embodiments, semiconductor substrate 104 may include a p-type dopant, which may include but is not limited to: boron (B), indium (In) and gallium (Ga). P-type dopants are elements introduced to semiconductor material to generate a free hole by “accepting” electron from semiconductor atom and “releasing” the hole at the same time. The dopant may be introduced to semiconductor substrate 104 in any now known or later developed fashion, e.g., in-situ doping during formation or ion implanting. As the doping technology used in this setting is well known in the art, no further detail is required.

Preliminary structure 102 may also include any now known or later developed trench isolation 106 in semiconductor substrate 104 to electrically isolate the eventually formed LDMOS transistor 100 (FIGS. 5A-9B) from other devices. As the techniques to form trench isolations 106 are well known no further details are required for understanding.

Preliminary structure 102 may also include a plurality of doped wells 110, 112 in semiconductor substrate 104. For purposes of description, doped wells 110, 112 include but are not limited to an n-type doped well (hereafter “n-well”) 110 surrounding a p-typed doped well (hereafter “p-well”) 112. Preliminary structure 102 formation also includes forming doped region 120 and doped region 122. Doped region 120 may take the form of a p-type doped well. Doped region 120 will be referenced as a region to differentiate from p-well 112; it is recognized that both are doped wells. Doped region 122 may take the form of an n-type doped well. Doped region 122 will be referenced as a region to differentiate from n-well 110; it is recognized that both are doped wells.

N-well 110, p-well 112, doped region 120 and doped region 122 may be formed using any now known or later developed semiconductor doping technique. For example, n-well 110, p-well 112 and doped regions 120, 122 may be formed by mask-directed doping by ion implantation followed by an anneal to drive in the dopants, in-situ doping during formation of substrate 104, and/or any other now known or later developed doping process. As noted, n-well 110 and doped region 122 may be doped with an n-type dopant. The n-type dopant of doped region 122 may be the same as n-well 110, but with a higher dopant concentration. Alternatively, the n-type dopants of each structure may be different. As will be described herein, doped region 122 may provide a drift region 142 (FIGS. 4-9B) (also known as a drain extension region) for transistor 100 (FIGS. 5A-9B). N-type dopants may include but are not limited to: phosphorous (P), arsenic (As), or antimony (Sb). N-type is an element introduced to semiconductor to generate free electrons by “donating” electrons to the semiconductor. P-well 112 and doped region 120 may be doped with a p-type dopant. The p-type dopant of p-well 112 may be the same as semiconductor substrate 104, but with a higher dopant concentration. The p-type dopant of doped region 120 may be the same as p-well 112 and/or semiconductor substrate 104, but with a higher dopant concentration. Alternatively, the p-type dopants of each structure may be different.

FIG. 1 also shows forming a polysilicon body layer 130 over a gate dielectric layer 132 over semiconductor substrate 104. That is, preliminary structure 102 may also include polysilicon body layer 130 over gate dielectric layer 132 over semiconductor substrate 104. Gate dielectric layer 132 may include any now known or later developed gate dielectric appropriate for an LDMOS transistor including but not limited to: silicon oxide, hafnium silicate, hafnium oxide, zirconium silicate, zirconium oxide, silicon nitride, silicon oxynitride, high-k material or any combination of these materials. Gate dielectric layer 132 may be formed using any now known or later developed semiconductor fabrication technique, e.g., deposition. “Depositing” may include any now known or later developed techniques appropriate for the material to be deposited including but are not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sput-tering deposition, ion beam deposition, electron beam deposition, laser assisted deposition, thermal oxidation, spin-on methods, physical vapor deposition (PVD), atomic layer deposition (ALD), chemical oxidation, molecular beam epitaxy (MBE), plating, evaporation. In one example, tetraethyl orthosilicate (TEOS) based ALD may be used to form silicon oxide. Gate dielectric layer 132 may have any desired thickness for a channel region 136 (dashed line in FIG. 2), i.e., active region, to be formed thereunder in semiconductor substrate 104.

Polysilicon body layer 130 may include any now known or later developed polysilicon material appropriate for a gate body in an LDMOS transistor, i.e., a polysilicon gate or a split gate field plate. Polysilicon body layer 130 may be formed by any appropriate deposition technique, e.g., ALD.

It will be recognized that preliminary structure 102, as shown in FIG. 1, is arranged to form LDMOS transistor 100 (FIGS. 5A-9B) with a field plate 190 (FIGS. 5A, 6A, 7A, 8A and 9A) (also known as a split gate field plate). Other forms of LDMOS transistors may include an additional trench isolation (not shown) in drift region 142 (FIGS. 4-9B) of LDMOS transistor 100 (FIGS. 5A-9B).

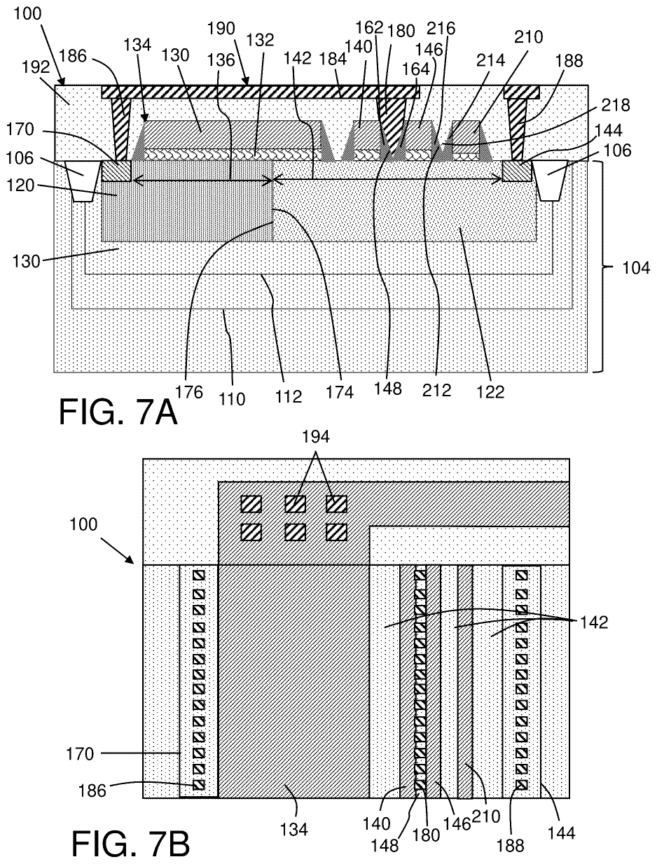

FIG. 2 shows a cross-sectional view of forming (part of) a polysilicon gate 134 over an (eventual) channel region 136 in semiconductor substrate 104. FIG. 2 also shows forming a first polysilicon member 140 over semiconductor substrate 104 and a second polysilicon member 146 over semiconductor substrate 104. First and second polysilicon members 140, 146 have a first space 148 therebetween. More particularly, FIG. 2 shows forming (part of) polysilicon gate 134 over (eventual) channel region 136 in semiconductor substrate 104, and forming first polysilicon member 140 over an (eventual) drift region 142 in semiconductor substrate 104 between polysilicon gate 134 and an (eventually formed) drain region 144 (FIGS. 4-9B) and second polysilicon member 146 over (eventual) drift region 142 between polysilicon gate 134 and (eventually formed) drain region 144 (FIG. 4-9B). First polysilicon member 140 is laterally spaced from polysilicon gate 134, and first and second polysilicon members 140, 146 are laterally spaced from one another. While not shown in FIGS. 1-2, some embodiments of the disclosure may also include forming a third polysilicon member 210 (FIGS. 7A-9B) over (eventual) drift region 142 (FIGS. 4-9B) with a second space 212 (FIGS. 7A-9B) between third polysilicon member 210 and an adjacent one of first and second polysilicon members 140, 146.

FIGS. 1 and 2 show patterning a mask 160 over an area in which polysilicon gate 134 and first and second polysilicon members 140, 146 (and third polysilicon member 210 (FIGS. 7A-9B)) are desired and etching (as indicated by vertical arrows in FIG. 1) polysilicon body layer 130 and gate dielectric layer 132. The etching may remove gate dielectric layer 132 from over semiconductor substrate 104, leaving it under polysilicon body layer 130. There are generally two categories of etching, (i) wet etch and (ii) dry etch. Wet etch is performed with a solvent (such as an acid) which may be chosen for its ability to selectively dissolve a given material (such as oxide), while, leaving another material (such as polysilicon) relatively intact. This ability to selectively etch given materials is fundamental to many semiconductor fabrication processes. A wet etch will generally etch a homogeneous material (e.g., oxide) isotropically, but a wet etch may also etch single-crystal materials (e.g. silicon wafers) anisotropically. Dry etch may be performed using a plasma. Plasma systems can operate in several modes by adjusting the parameters of the plasma. Ordinary plasma etching produces energetic free radicals, neutrally charged, that react at the surface of the wafer. Since neutral particles attack the wafer from all angles, this process is isotropic. Ion milling, or sputter etching, bombards the wafer with energetic ions of noble gases, which approach the wafer approximately from one direction, and therefore this process is highly anisotropic. Reactive-ion etching (RIE) operates under conditions intermediate between sputter and plasma etching and may be used to produce deep, narrow features, such as STI trenches. Here, a RIE may be used to remove polysilicon body layer 130 and gate dielectric layer 132. Once etching is complete, mask 160 may be removed using any known removal process appropriate for the mask material, e.g., a wet etch for hard nitride mask or an ashing process (oxygen dry strip process) for a soft resist-based mask.

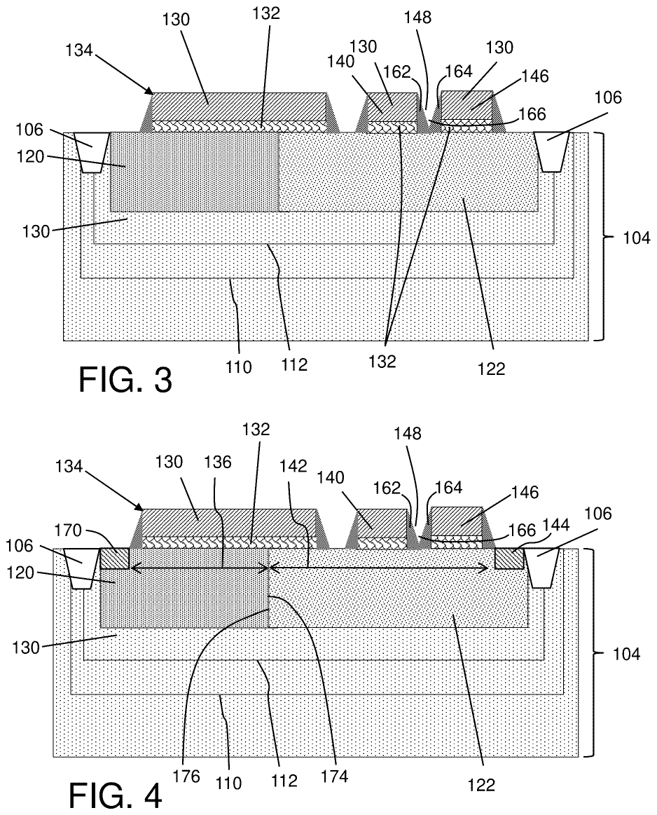

FIG. 3 shows a cross-sectional view forming spacers for polysilicon gate 134 and first and second polysilicon members 140, 146. More particularly, FIG. 3 shows forming a first spacer 162 in first space 148 adjacent first polysilicon member 140 and forming a second spacer 164 in first space 148 adjacent second polysilicon member 146. As understood, spacers 162, 164 may wrap around first and second polysilicon members 140, 146, respectively. As shown, although not necessary in all cases, first space 148 may be sized such that first and second spacers 162, 164 contact one another and, collectively, cover semiconductor substrate 104. In this setting, first and second spacer 162, 164 create a pointed trench bottom 166 in first space 148. Spacers (not labeled) may also be formed adjacent opposing sides of polysilicon gate 134, and spacers 162, 164 may extend around outer sides of first and second polysilicon members 140, 146. Spacers 162, 164 may be formed using any now known or later developed process, e.g., depositing spacer material and etching. Spacers 162, 164 may include any now known or later developed spacer material such as but not limited to silicon nitride.

FIG. 4 shows a cross-sectional view of forming, among other things, a source region 170 and a drain region 144 configured for LDMOS transistor 100 (FIGS. 5A-9B) in semiconductor substrate 104. Source/drain regions 170, 144 may be formed using any now known or later developed semiconductor doping technique. For example, source/drain regions 170, 144 may be formed by mask-directed doping by ion implantation (not shown) followed by an anneal to drive in the dopants. The various trench isolations 106 and spacers on polysilicon gate 134 and second polysilicon member 146 may also self-align source/drain regions 170, 144. Source/drain regions 170, 144 may be doped with any n-type dopant as described herein. Source region 170 may optionally also include an additional doped region (not shown), which may be p-type doped but with a higher concentration than doped region 120. Doped region 120 (e.g., a p-well) extends around source region 170 (n+doped region) in semiconductor substrate 104 and doped region 122 (n-well) extends around drain region 144 (n+ doped region) in semiconductor substrate 104, respectively.

As understood in the field, a space between source region 170 and an edge 174 of doped region 120 defines channel region 136 of the device; and a space between an edge 176 of doped region (n-well) 122 and drain region 144 defines drift region 142 (also known as a drain extension region). While edges 174, 176 are shown as co-linear, that is not necessary in all instances.

It is understood that LDMOS transistor 100 may also be formed in a manner that two transistors share a single drain region 144 and doped region (n-well) 122. In this case, preliminary structure 102 would include another source region 170 and doped region 120 mirrored to the right of drain region 144.

FIGS. 5A-B show corresponding cross-sectional and top-down views, respectively, of forming interconnects to, among other things, source/drain regions 170, 144 and first and second polysilicon members 140, 146. More particularly, FIG. 5A shows forming a first contact 180 including a lower portion 182 positioned in first space 148 between first and second polysilicon members 140, 146. As illustrated, first space 148 with first and second spacers 162, 164 position a bottom of lower portion 182 of contact 180 vertically spaced from and electrically isolated from drift region 142. FIG. 5A also shows forming contacts 186, 188 to source region 170 and drain region 144, respectively. Contacts 194 (FIG. 5B) to polysilicon gate 134 may also be formed with contacts 180, 186, 188. FIG. 5A also shows forming a metal layer 184 over polysilicon gate 134 and first and second polysilicon members 140, 146. Metal layer 184 may also be referred to herein as a metal field plate. Metal layer 184 (i.e., a metal wire) is electrically coupled to contact 180. In certain embodiments, as shown in FIG. 5A, field plate 190, i.e., metal layer 184 thereof, may be electrically connected to source region 170, e.g., by contact(s) 186. That is, contact(s) 186 may electrically connect metal layer 184 to source region 170, so field plate 190 is coupled to source region 170. Where this connection is provided, it reduces gate to drain capacitance to reduce parasitic capacitance. As understood in the field, metal layer 184, first and second polysilicon members 140, 146 and first contact 180 (and contact 186, where provided) may collectively provide a field plate 190 for transistor 100 (FIGS. 5A-9B).

Contacts 180, 186, 188, 194 and metal layer 184 (collectively, interconnects) may be formed using any now known or later developed interconnect forming processes. For example, any now known or later developed salicidation process may be performed on source/drain regions 170, 144, polysilicon gate 134 and/or polysilicon members 140, 146. Silicide may be formed using any now known or later developed technique, e.g., performing an in-situ pre-clean, depositing a metal such as titanium, nickel, cobalt, etc., annealing to have the metal react with silicon or polysilicon, and removing unreacted metal. The interconnects can be formed using any now known or later developed techniques such as but not limited to depositing one or more interlayer dielectric (ILD) layers 192, forming openings for contacts and/or metal layer/wire, depositing a refractory metal liner and conductor, and planarizing. ILD layers 192 may include any currently-known or later developed substance for providing electrical insulation, and as examples may include: silicon nitride, silicon oxide, fluorinated silicon oxide (FSG), hydrogenated silicon oxycarbide (SiCOH), porous SiCOH, boro-phospho-silicate glass (BPSG), silsesquioxanes, carbon (C) doped oxides (i.e., organosilicates) that include atoms of silicon (Si), carbon (C), oxygen (O), and/or hydrogen (H), thermosetting polyarylene ethers, a spin-on silicon-carbon containing polymer material, or layers thereof. Although not shown, in certain embodiments, contact 180 may be partially on (i.e., partially land on) polysilicon members 140, 146 over drift region 142 in semiconductor substrate 104 between polysilicon gate 134 and drain region 144.

FIGS. 5A-B also show corresponding cross-sectional and top-down views, respectively, of LDMOS transistor 100 according to embodiments of the disclosure. Referring to FIGS. 5A-B, embodiments of LDMOS transistor 100 structure will now be described. LDMOS transistor 100 includes semiconductor substrate 104, which may include, for example, a semiconductor fin or bulk semiconductor substrate. LDMOS transistor 100 also includes polysilicon gate 134 over channel region 136 in semiconductor substrate 104, source region 170 to a first side (left as illustrated) of polysilicon gate 134, and drain region 144 to a second, opposite side (right as illustrated) of polysilicon gate 134. LDMOS transistor 100 also includes drift region 142 in semiconductor substrate 104 between polysilicon gate 134 and drain region 144, i.e., provided by part of doped region (n-well) 122.

LDMOS transistor 100 also includes first polysilicon member 140 over drift region 142, and second polysilicon member 146 over drift region 142 between polysilicon gate 134 and drain region 144. First and second polysilicon members 140, 146 are electrically isolated or “floating” structures. First and second polysilicon members 140, 146 have first space 148 therebetween. Polysilicon gate 134 and first and second polysilicon members 140, 146 includes polysilicon body layer 130 and gate dielectric layer 132 between polysilicon body layer 130 and semiconductor substrate 104. Hence, gate dielectric layer 132 is between polysilicon gate 134 and semiconductor substrate 104 and between first and second polysilicon members 140, 146 and drift region 142. (Note, polysilicon body layer 130 and gate dielectric layer 132 are labeled for polysilicon members 140, 146 in FIG. 3 only, for clarity purposes). Polysilicon gate 134 and polysilicon members 140, 146 thus each include polysilicon body layer 130 over a continuous planar surface of semiconductor substrate 104.

LDMOS transistor 100 also includes metal layer 184 over polysilicon gate 134 (and a portion of at least first polysilicon member 140 and perhaps both first and second polysilicon members 140, 146). Metal layer 184 is also over contact 180 that extends from metal layer 184. Contact 180 includes lower portion 182 positioned in first space 148 between first and second polysilicon members 140, 146. LDMOS transistor 100 may also include first spacer 162 in first space 148 adjacent first polysilicon member 140 and second spacer 164 in first space 148 adjacent second polysilicon member 146. First and second spacers 162, 164 may contact one another so as to position a bottom of lower portion 182 vertically spaced from and electrically isolated from drift region 142. That is, a bottom of lower portion 182 of contact 180 is vertically above a lower end of polysilicon members 140, 146 and gate dielectric layer 132, so contact 180 is electrically isolated from drift region 142 by spacers 162, 164. As noted, metal layer 184, first and second polysilicon members 140, 146 and first contact 180 (and contact 186, where provided) provide field plate 190 for LDMOS transistor 100.

As shown in the top-down view FIG. 5B, first and second polysilicon members 140, 146 extend parallel to one another (into and out of page of FIG. 5A). (Note, the top-down views used herein are from a first contact level downwardly, and do not show, among other things, the metal layer and the spacers for clarity of illustration. Also, the top-down views used herein are not at the same scale as the corresponding cross-sectional views for clarity of illustration). Contact(s) 194 are also shown electrically connected to polysilicon gate 134. As shown in FIG. 5B, although not necessary in all cases, each contact 180, 186, 188 and 194 may include a plurality of spaced contacts. In certain embodiments, shown in FIGS. 5A-B, contact(s) 180 to first and second polysilicon member 140, 146 may include vertical pillar(s). That is, contact(s) 180 include generally vertically extending conductor(s), e.g., with circular or square horizontal cross-sections. However, as will be described, other contact structures are also possible.

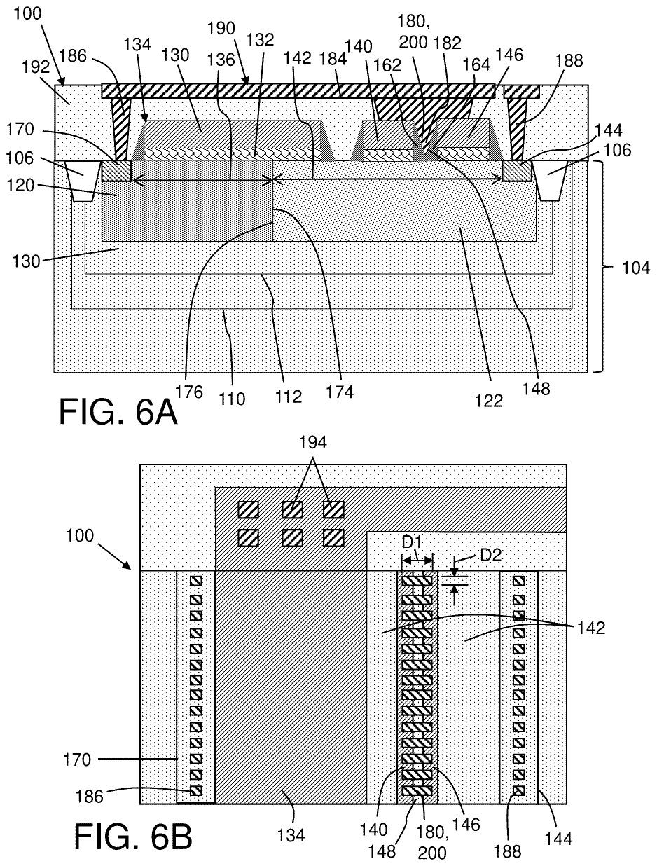

FIGS. 6A-B, 7A-B and 8A-B show corresponding cross-sectional and top-down views, respectively, of LDMOS transistor 100 according to other embodiments of the disclosure.

In other embodiments, as shown in FIGS. 6A-B, contact(s) 180 may each include a contact bar 200. As shown in FIG. 6B, contact bar(s) 200 have a first dimension D1 defined between or over first and second polysilicon members 140, 146 greater than a second dimension D2 defined along first and second polysilicon members 140, 146. Hence, contact bar(s) 200 may have a rectangular horizontal cross-section. As with contact 180, a bottom or lower portion 182 of contact bar(s) 200 is isolated from drift region 142 by spacers 162, 164.

In other embodiments, as shown in FIGS. 7A-B, LDMOS transistor 100 may include a third polysilicon member 210 over drift region 142 in semiconductor substrate 104 between polysilicon gate 134 and drain region 144. A second space 212 is between third polysilicon member 210 and an adjacent one of first and second polysilicon members 140, 146 (shown as second polysilicon member 146). A spacer 214 of third polysilicon member 210 and a spacer 216 (perhaps part of second spacer 164 (FIGS. 5A-B)) of second polysilicon member 146 may also be provided. In this setting, spacers 214, 216 create a pointed trench bottom 218 in second space 212, i.e., that covers and electrically isolates drift region 142 in semiconductor substrate 104. Third polysilicon member 210 and spacers 214, 216 may be formed in the same manner as described herein for first and second polysilicon members 140, 146 and spacers 162, 164, respectively. As shown in FIG. 7B, first, second and third polysilicon members 140, 146, 210 extend parallel to one another. FIGS. 7A-B show an embodiment in which third polysilicon member 210 is electrically isolated from (i.e., floating relative to) first and second polysilicon members 140, 146.

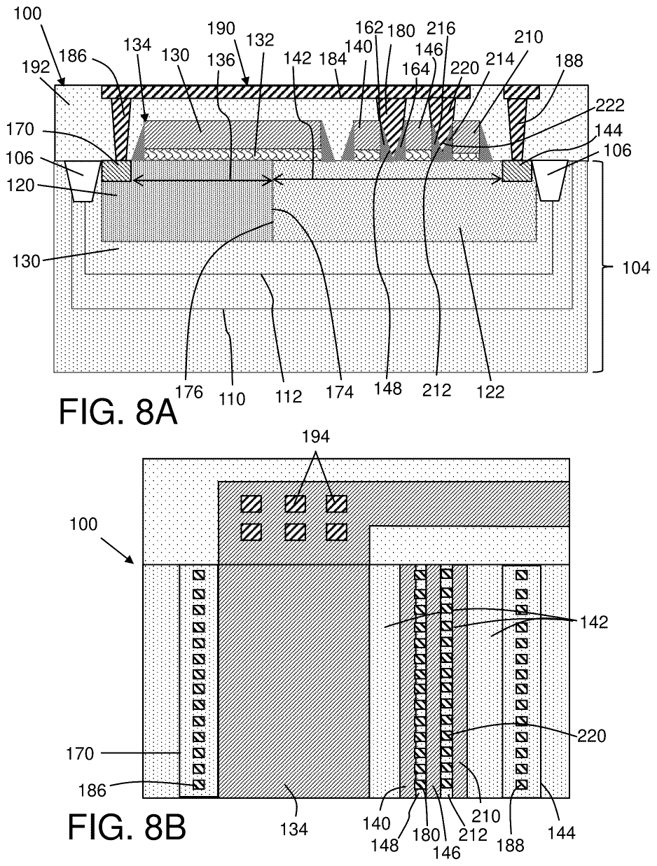

In other embodiments, as shown in FIGS. 8A-B, LDMOS transistor 100 may include a third polysilicon member 210 over drift region 142 in semiconductor substrate 104 between polysilicon gate 134 and drain region 144, as in FIGS. 7A-B. Further, second space 212 is between third polysilicon member 210 and an adjacent one of first and second polysilicon members 140, 146 (shown as second polysilicon member 146). Spacer 214 of third polysilicon member 210 and spacer 216 (perhaps part of second spacer 164) of second polysilicon member 146 may also be provided. In this setting, contact(s) 220 extends from metal layer 184 (separate from contact 180) and includes a lower portion 222 positioned in second space 212 between third polysilicon member 210 and the adjacent one of first and second polysilicon members 140, 146 (shown as second polysilicon member 146). As with contact 180, a bottom of lower portion 222 is isolated from drift region 142 by spacers 214, 216. Contact 220 may be formed in a similar manner, and perhaps at the same time, as contact(s) 180, as described herein. In some embodiments, first space 148 can be wider than second space 212. As a result, the thickness of spacer material at the bottom center of first space 148 will be less than the thickness of spacer material at the bottom center of second spacer 212. Thus, contact 220 will be separated from drift region 142 by a greater distance than contact 180. Such a multi-level structure can be employed to achieve the desired electric field within drift region 142 (e.g., a uniform electric field between channel region 136 and drain region 144).

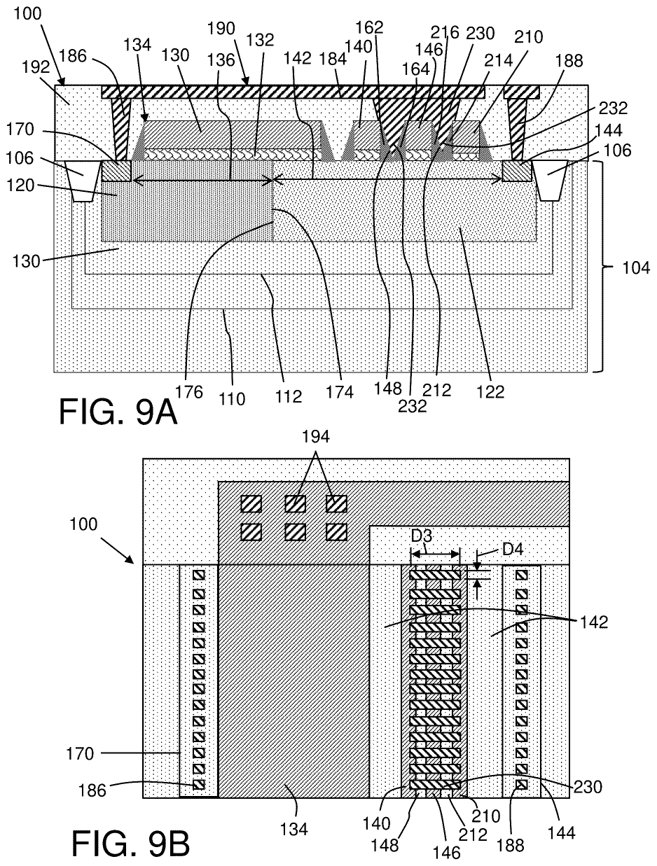

In other embodiments, as shown in FIGS. 9A-B, LDMOS transistor 100 may include a third polysilicon member 210 over drift region 142 in semiconductor substrate 104 between polysilicon gate 134 and drain region 144, as in FIGS. 7A-B and 8A-B. Further, second space 212 is between third polysilicon member 210 and an adjacent one of first and second polysilicon members 140, 146 (shown as second polysilicon member 146). Spacer 214 of third polysilicon member 210 and spacer 216 (perhaps part of second spacer 164) of second polysilicon member 146 may also be provided. In this setting, a contact bar 230 is provided. Contact bar 230 as with contact bar 200 in FIGS. 6A-B, has a first dimension D3 defined between or over adjacent polysilicon members 140, 146 or 146, 210 greater than a second dimension D4 defined along adjacent polysilicon members 140, 146 or 146, 210. In this setting, contact bar 230 may extends over at least a middle one of the first, second and third polysilicon members 140, 146, 210 (second polysilicon member 146 as shown) and includes a lower portion(s) 232 positioned in first space 148 and second space 212. It will be recognized that contact bar 230 can also extend entirely over first polysilicon member 140 and/or third polysilicon member 210. Contact bar 230 may be formed in a similar manner, and perhaps at the same time, as contact(s) 186, 188, as described herein.

While LDMOS transistor 100 has been described herein with a particular dopant configuration to form a certain polarity device, it will be recognized that the dopant configurations can be switched or otherwise modified to create a different polarity device or the same type polarity device but with different operational characteristics.

Embodiments of the disclosure provide various technical and commercial advantages, examples of which are discussed herein. The polysilicon members in the drift region improves the prompt degradation of the LDMOS transistor due to the high-quality gate dielectric layer at the bottom of the polysilicon members. The contact of the LDMOS transistor also results in increased breakdown voltage.

The structure and method as described above are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A laterally-diffused metal-oxide semiconductor (LDMOS) transistor, comprising:
a semiconductor substrate;
a polysilicon gate over a channel region in the semiconductor substrate;
a source region to a first side of the polysilicon gate;
a drain region to a second, opposite side of the polysilicon gate;
a metal layer over the polysilicon gate;
a drift region in the semiconductor substrate between the polysilicon gate and the drain region;
a first polysilicon member over the drift region;
a second polysilicon member over the drift region, the first and second polysilicon members having a first space therebetween; and
a first contact extending from the metal layer and including a lower portion positioned in the first space between the first and second polysilicon members.

2. The LDMOS transistor of claim 1, wherein a bottom of the lower portion of the first contact is vertically spaced and electrically isolated from the drift region.

3. The LDMOS transistor of claim 1, further comprising a first spacer in the first space adjacent the first polysilicon member and a second spacer in the first space adjacent the second polysilicon member, wherein the first spacer and the second spacer contact one another and position a bottom of the lower portion vertically spaced from and electrically isolated from the drift region.

4. The LDMOS transistor of claim 1, wherein the first and second polysilicon members extend parallel to one another, and the first contact includes a contact bar having a first dimension defined between or over the first and second polysilicon members greater than a second dimension defined along the first and second polysilicon members.

5. The LDMOS transistor of claim 1, further comprising a third polysilicon member over the drift region in the semiconductor substrate between the polysilicon gate and the drain region, and a second space between the third polysilicon member and an adjacent one of the first and second polysilicon members.

6. The LDMOS transistor of claim 5, further comprising a second contact extending from the metal layer and including a lower portion positioned in the second space between the third polysilicon member and the adjacent one of the first and second polysilicon members.

7. The LDMOS transistor of claim 5, wherein the first, second and third polysilicon members extend parallel to one another, and further including a contact bar having a first dimension defined between or over adjacent polysilicon members greater than a second dimension defined along adjacent polysilicon members, wherein the contact bar extends over at least a middle one of the first, second and third polysilicon members and includes a lower portion positioned in the first space and the second space.

8. The LDMOS transistor of claim 1, further comprising a second contact electrically connecting the metal layer to the source region.

9. The LDMOS transistor of claim 1, further comprising a gate dielectric layer between the polysilicon gate and the semiconductor substrate and between the first and second polysilicon members and the drift region.

10. A laterally diffused metal-oxide semiconductor (LDMOS) transistor, comprising:
a semiconductor substrate;
a polysilicon gate over a channel region in the semiconductor substrate;
a source region to a first side of the polysilicon gate;
a drain region to a second, opposite side of the polysilicon gate;
a metal field plate over the polysilicon gate;
a drift region in the semiconductor substrate between the polysilicon gate and the drain region;
a first polysilicon member over the drift region;
a second polysilicon member over the drift region, the first and second polysilicon members having a first space therebetween;
a first spacer in the first space adjacent the first polysilicon member;
a second spacer in the first space adjacent the second polysilicon member; and
a first contact extending from the metal field plate and including a lower portion positioned in the first space between the first and second polysilicon members, wherein a bottom of the lower portion of the first contact is vertically spaced and electrically isolated from the drift region by the first and second spacers.

11. The LDMOS transistor of claim 10, wherein the first spacer and the second spacer contact one another to position the bottom of the lower portion vertically spaced from and electrically isolated from the drift region.

12. The LDMOS transistor of claim 10, wherein the first and second polysilicon members extend parallel to one another, and the first contact includes a contact bar having a first dimension defined between or over the first and second polysilicon members greater than a second dimension defined along the first and second polysilicon members.

13. The LDMOS transistor of claim 10, further comprising a third polysilicon member over the drift region, and a second space between the third polysilicon member and an adjacent one of the first and second polysilicon members.

14. The LDMOS transistor of claim 13, further comprising a second contact extending from the metal field plate and including a lower portion positioned in the second space between the third polysilicon member and the adjacent one of the first and second polysilicon members.

15. The LDMOS transistor of claim 14, wherein the first, second and third polysilicon members extend parallel to one another, and further including a contact bar having a first dimension defined between or over adjacent polysilicon members greater than a second dimension defined along adjacent polysilicon members, wherein the contact bar extends over at least a middle one of the first, second and third polysilicon members and includes a lower portion positioned in the first space and the second space.

16. The LDMOS transistor of claim 10, further comprising a second contact electrically connecting the metal field plate to the source region.

17. The LDMOS transistor of claim 10, further comprising a gate dielectric layer between the polysilicon gate and the semiconductor substrate and between the first and second polysilicon members and the drift region.

18. A method, comprising:
forming a polysilicon gate over a channel region in a semiconductor substrate;
forming a first polysilicon member over the semiconductor substrate and a second polysilicon member over the semiconductor substrate, the first and second polysilicon members having a first space therebetween;
forming a source region and a drain region on opposing sides of the polysilicon gate, wherein a drift region is between the polysilicon gate and the drain region in the semiconductor substrate and the first polysilicon member the second polysilicon member are over the drift region;
forming a first contact including a lower portion positioned in the first space between the first and second polysilicon members; and
forming a metal layer over the polysilicon gate and the first and second polysilicon members, the metal layer contacting the first contact.

19. The method of claim 18, further comprising forming a first spacer in the first space adjacent the first polysilicon member and forming a second spacer in the first space adjacent the second polysilicon member, wherein the first spacer and the second spacer contact one another and position a bottom of the lower portion of the contact vertically spaced from and electrically isolated from the drift region.

20. The method of claim 18, further comprising forming a third polysilicon member over the drift region, and a second space between the third polysilicon member and an adjacent one of the first and second polysilicon members.
